(19) United States
(12) Patent Application Publication
(10) Pub. No.: US 2007/0204192 A1
(43) Pub. Date: Aug. 30, 2007

(54) METHOD FOR DETECTING DEFECTS OF A CHIP

(76) Inventors: Jia-Siang Yeh, Kao-Hsiung Hsien (TW); Chun-Sheng Wang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/307,884

(22) Filed: Feb. 27, 2006

(51) Int. Cl. G01R 31/28

(52) U.S. Cl. 714/726

(57) ABSTRACT

A method for detecting a defect of a chip includes: utilizing a plurality of scan patterns to scan a plurality of scan chains of the chip; for each of the scan patterns, obtaining a suspected defect set and an unsuspected defect set; obtaining an intersection of all suspected defect sets corresponding to the scan patterns; obtaining an union of all unsuspected defect sets corresponding to the scan patterns; subtracting the union from the intersection to obtain a resultant suspected defect set; and detecting the defect of the chip according to the resultant suspected defect set.

### BACKGROUND OF THE INVENTION

1. Field of the Invention

The present invention relates to chip testing, and more particularly, to a method for detecting defects of a chip.

2. Description of the Prior Art

Accurate fault diagnosis is an increasingly important aspect of testing integrated circuits (IC), especially in view of increasing gate counts and shrinking feature sizes.

In general, when a chip is being tested, a signal is often injected into a chip under testing to see whether the chip can work normally. Traditionally, the chip test utilizes a stuck-at fault model. This model assumes that if a certain node is defined as a defect, the certain node can be simulated as either a stuck-at one fault or a stuck-at zero fault. In other words, the certain node can be simulated as being fixed at either a high voltage level (logic level 1) or a ground level (logic level 0).

Scanning is the most frequently utilized technique nowadays for testing a chip. The scan testing is performed in the following steps. As is well known, a chip often comprises many memory devices (such as flip-flops and latches). Therefore, these memory devices inside the chip are firstly connected as a plurality of scan chains. The scan chains work as shifting registers. This also implies that the content (data) of the memory devices (the scan chain) can be accessed in a shifting way. In other words, in the scan testing procedure, a scan pattern can be shifted-in to the scan chain for injecting the signal into the chip in order to test the chip, and the test result can be shifted-out from the scan chain to check if the test result complies with the expected desired values.

Furthermore, a fault simulation is performed to know the nodes of each scan pattern tests. After the test result is compared with expected values, a fail log can be obtained. The fail log can show which flip-flop does not output the expected value. Because the nodes corresponding to the above-mentioned flip-flop can be determined through the fault simulation, these nodes may be determined as suspected defects. In other words, the suspected defects and unsuspected defects can be determined according to the fail log and the result of the fault simulation. After analyzing the suspected defects and unsuspected defects, the most likely defect can also be determined.

After the defects are determined, the chip manufacturer is able to fix the semiconductor manufacturing process of the chip to make the yield better, and further reduce the costs.

Unfortunately, the above-mentioned testing procedure suffers from several problems. Firstly, the result of the fault simulation often requires huge amounts of data, and therefore, in practical applications, only a few scan patterns can be utilized in the fault simulation in order to save time and hardware resources. This reduces the accuracy of determining the candidate defect locations.

Secondly, in the prior art, a fault simulation has to be performed on a chip to deal with a fail log, but the fault simulation takes large amounts of time and needs a lot of memory spaces in order to be performed. Therefore, it is not practical to simultaneously test many chips because the resource consumption is too huge.

Thirdly, although the suspected and unsuspected defects corresponding to the scan patterns can be determined according to the fail log and the fault simulation, it is still hard to find out the most likely defect from the suspected defects. That is, chip designers may use different algorithms to analyze the suspected and unsuspected defects to determine the most possible defect, but the hit rate (accuracy) of the candidate defect determined by the algorithm may be poor.

### SUMMARY OF THE INVENTION

It is therefore one of the primary objectives of the claimed invention to provide a method for detecting a defect of a chip, to solve the above-mentioned problem.

According to an exemplary embodiment of the claimed invention, a method for detecting a defect of a chip is disclosed. The method comprises: utilizing a plurality of scan patterns to scan a plurality of scan chains of the chip; for each of the scan patterns, obtaining a suspected defect set and an unsuspected defect set; obtaining an intersection of all suspected defect sets corresponding to the scan patterns; obtaining a union of all unsuspected defect sets corresponding to the scan patterns; subtracting the union from the intersection to obtain a resultant suspected defect set; and detecting the defect of the chip according to the resultant suspected defect set.

According to another exemplary embodiment of the claimed invention, a method for detecting a defect of a chip is disclosed. The method comprises: utilizing a plurality of scan patterns to scan a plurality of scan chains of the chip, each of the scan chains comprising a plurality of flip-flops; for each of the scan patterns, obtaining a suspected defect set of a specific flip-flop and an unsuspected defect set of all of the scan chains; obtaining a first union of all suspected defect sets of the specific flip-flop; obtaining a second union of all unsuspected defect sets corresponding to the scan patterns; subtracting the second union from the first union to obtain a resultant suspected defect set; and detecting the defect of the chip according to the resultant suspected defect set.

According to another exemplary embodiment of the claimed invention, a method for detecting a defect of a chip comprises: utilizing a plurality of scan patterns to scan a plurality of scan chains of the chip; building a fault dictionary through performing fault simulations, where the fault dictionary comprises a plurality of entries each having a flip-flop name; compressing the fault dictionary to generate a compressed fault dictionary by grouping a plurality of specific entries corresponding to a specific flip-flop name and deleting repeated specific flip-flop names in the specific entries; obtaining the suspected defect set and the unsuspected defect set through looking up the compressed fault dictionary; and analyzing the suspected defects and the unsuspected defects to determine the defect of the chip.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a fault diagnosis for testing a chip according to the present invention.

FIG. 2 is a flow chart of a process of analyzing the suspected and unsuspected defects in the step 110 shown in FIG. 1.

FIG. 3 is a simplified diagram illustrating the analysis based on the single stuck-at fault assumption according to the present invention.

FIG. 4 is a simplified diagram illustrating the multiple stuck-at fault assumption where a single fault locates on a single scan chain according to the present invention.

FIG. 5 is a diagram illustrating how an original fault dictionary is compressed into a compressed dictionary.

### DETAILED DESCRIPTION

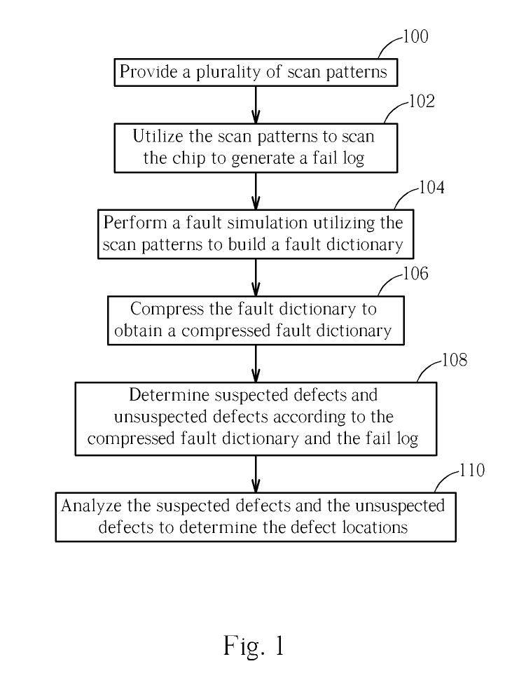

Please refer to FIG. 1, which is a flow chart of a fault diagnosis for testing a chip according to the present invention. It comprises the following steps:

Step 100: Provide a plurality of scan patterns;

Step 102: Utilize the scan patterns to scan the chip to generate a fail log;

Step 104: Perform a fault simulation utilizing the scan patterns to build a fault dictionary;

Step 106: Compress the fault dictionary to obtain a compressed fault dictionary;

Step 108: Determine suspected defects and unsuspected defects according to the compressed fault dictionary and the fail log.

Step 110: Analyze the suspected defects and the unsuspected defects to determine the defect locations.

First, a plurality of scan patterns are provided (step 100). As is known, the scan patterns can be provided by automatic test program generation (ATPG). The automatic test program generation is a tool capable of generating scan patterns automatically according to different circuits under testing. This means the chip designer can utilize the ATPG to generate appropriate scan patterns, and these scan patterns are utilized to scan the chip for testing.

Then, the scan patterns are utilized to test the chip. As mentioned previously, the scan patterns are sequentially shifted-in into the scan chains of the chip. The test results are obtained by shifting out data from the scan chains, and the test results are recorded in a fail log (step 102). For example, the fail log comprises information including failure scan patterns, failure scan chain numbers, and failure cycles (the failure cycles indicates the failure flip-flops). The information can be used in cooperation with the result of the fault simulation.

A fault simulation is performed according to the scan patterns. As mentioned previously, the fault simulation is used to identify nodes of each scan pattern. Please note that in the present invention, the fault simulation is previously performed to build a fault dictionary (Step 104). That is, the results of the fault simulation are gathered inside the fault dictionary. Therefore, if the fail log is generated, as long as the fault dictionary is looked up according to the fail log, the suspected defects (meaning failed nodes) and unsuspected defects (meaning the nodes which pass) can be determined.

Please note, because the result of fault simulation has huge data amount, if the fault dictionary is directly looked-up, a large amount of time will be spent. Therefore, in the present invention, the fault dictionary is compressed (step 106) to reduce the total data amount of the fault dictionary. Please note that the compressing technique will be illustrated in the following disclosure, and is thus omitted here.

The compressed fault dictionary can significantly help to sort suspected defects (faults) and unsuspected defects according to the fail log. In other words, the complexity of looking-up the fault dictionary is reduced such that the suspected defects and unsuspected defects can be more easily determined (step 108).

At last, the suspected defects and the unsuspected defects are analyzed to determine the defect locations (step 110). The chip manufacturer (for example, engineers in the lab) can fix the semiconductor process of the chip according to the defect locations. Please note that the present invention process of analyzing the suspected defects and the unsuspected defects will be illustrated in the following disclosure, and is thus omitted here.

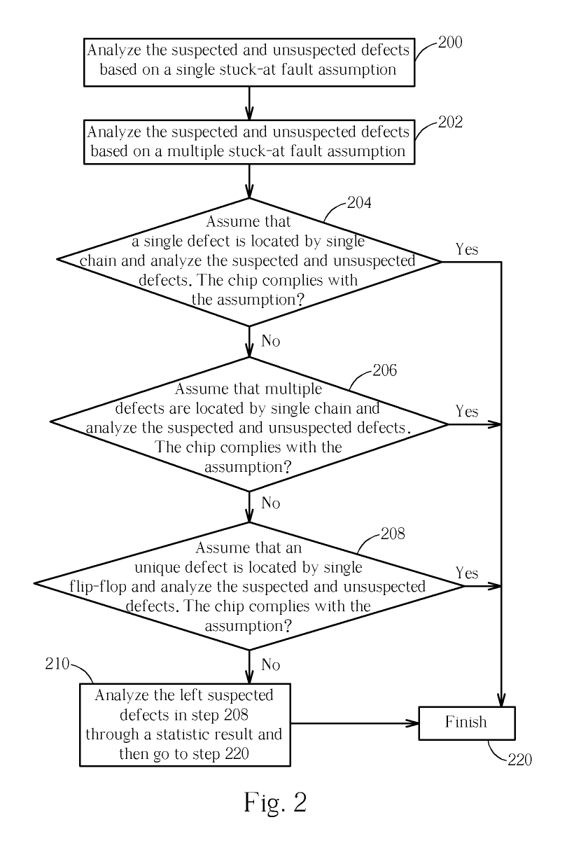

Please note, in the following disclosure, the analysis of suspected defects and unsuspected defects in the step 110 of FIG. 1 are illustrated. Please refer to FIG. 2, which is a flow chart of a process of analyzing the suspected and unsuspected defects in the step 110 shown in FIG. 1. The process of analyzing the suspected and unsuspected defects comprises the following steps:

Step 200: Analyze the suspected and unsuspected defects based on a single stuck-at fault assumption.

Step 202: Analyze the suspected and unsuspected defects based on a multiple stuck-at fault assumption.

Step 204: Assume that a single defect is located by single chain and analyze the suspected and unsuspected defects; if the chip complies with the assumption, then go to step 220; otherwise, go to step 206.

Step 206: Assume that multiple defects are located by single chain and analyze the suspected and unsuspected defects; if the chip complies with the assumption, then go to step 220; otherwise, go to step 208.

Step 208: Assume that a unique defect is located by single flip-flop and analyze the suspected and unsuspected defects; if the chip complies with the assumption, then go to step 220; otherwise, go to step 210.

Step 210: Analyze the left suspected defects in step 208 through a statistic result and then go to step 220.

Step 220: Finish.

Please note, in FIG. 2, the hit rate (accuracy) of the determined defect is higher if the defect can be determined in a more previous step. This means that the hit rate of the defect in step 200 is higher than that of step 202, the hit rate of the defect in step 206 is higher than step 208, and so on. Therefore, in a preferred embodiment of the present invention, the above-mentioned steps 200˜220 are orderly performed. This enables the hit rate of the defect to be as high as possible when the defect is determined. In other embodiments, however, these analyses of steps 200˜210 can be performed simultaneously to determine all possible defects, including a defect based on the single stuck at fault assumption and defects based on the multiple stuck at fault assumption. Furthermore, the operation of each step 200˜220 will be illustrated as follows.

First of all, the suspected and unsuspected defects are analyzed through a single stuck-at fault assumption (step 200). The single stuck-at fault assumption means that it is assumed the entire chip has only one stuck-at defect. As known by those skilled in the art, as long as a chip is defective, the chip is often influenced by multiple defects instead of only one defect. Therefore, single stuck-at fault assumption has many restrictions. If the chip is determined to have only one defect, only one defect is likely to be the real one. The hit rate of the determined defect based on the single stuck-at fault assumption is the highest.

The method of determining the defect through analyzing the suspected and unsuspected defects based on a single stuck-at fault assumption is illustrated as the following equation.
Single Defect located on the entire chip=suspected defect sets_allchains(AND)−unsuspected defect sets_allchains(OR) equation (1)

Please note that in equation (1), suspected defects_allchains(AND) is equal to the intersection of all suspected defect sets of all of the scan chains corresponding to each scan pattern, and the unsuspected defects_allchains(OR) is equal to the union of unsuspected defect sets of all of the scan chains corresponding to each scan pattern.

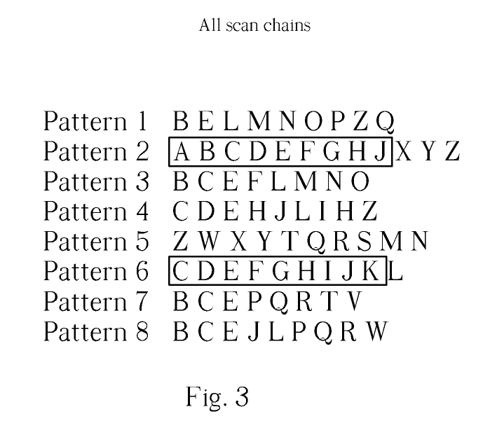

Please refer to FIG. 3, which is a simplified diagram illustrating the analysis based on the single stuck-at fault assumption according to the present invention. In FIG. 3, each scan pattern corresponds to multiple characters, where each character represents a node of the chip and the characters corresponding to each pattern show the condition of the nodes of all scan chains. The characters in the grid are suspected defects (this means these characters in the grid represent failed nodes), and others are unsuspected defects. For example, take a look at scan pattern 1, where the characters B, E, L, M, N, O, P, Z, Q represents the nodes which scan pattern 1 can detect. They are all good (i.e. unsuspected defects). Similar to scan pattern 3, the characters A, B, C, D, E, F, G, H, J, X, Y, Z are the nodes which scan pattern 3 can detect. The nodes A, B, C, D, E, F, G, H, J are suspected defects, and the nodes X, Y, Z are unsuspected defects. For instance, the nodes A, B, C, D, E, F, G, H, J may correspond to a flip-flop which outputs an unexpected value.

Please note, in the real implementation, each scan pattern may correspond to thousands of nodes, and more scan patterns are utilized. In FIG. 3, however, only 8 scan patterns are shown and each scan pattern only corresponds to a few nodes. This is only an example for simply illustrating the present invention.

In the single stuck-at fault assumption, the chip is only affected by one defect. Therefore, the intersection of suspected defect sets of all scan chains for each scan pattern is obtained first because the nodes in the intersection are more likely to be the real defect. In the case shown in FIG. 3, for each scan pattern, a suspected defect set and an unsuspected defect set are obtained. For example, for scan pattern 1, the suspected defect set of the scan pattern 1 is null and the unsuspected defect set of the scan pattern 1 comprises elements B, E, L, M, N, O, P, Z, Q. For scan pattern 3, the nodes A, B, C, D, E, F, G, H, J belong to the suspected defect set and the other nodes X, Y, Z belong to the unsuspected defect set.

In equation (1), the intersection of all suspected defect sets should be obtained. As shown In FIG. 3, it is easily seen that the intersection of all suspected defect sets should be the intersection of “A, B, C, D, E, F, G, H, J” and “C, D, E, F, G, H, I, J, K”. Therefore, the intersection will be “C, D, E, F, G, H, J”.

On the other hand, the union of all unsuspected defect sets is obtained. Because the nodes in the union pass at least one scan pattern, the resultant defect set of subtracting the union from the intersection should comprise remaining suspected defects. If the result defect set comprises only one defect, (the number of the remaining suspected defects is 1), this means that the resultant defect set complies with the single stuck-at assumption. Therefore, the left defect inside the resultant defect set is determined as the candidate defect and reported to the lab. In the example shown in FIG. 3, nodes C, D, E, H are unsuspected defects in scan pattern 4, the node F is an unsuspected defect in scan pattern 3, and the node is an unsuspected defect in scan pattern 8. Therefore, after subtracting the union from the intersection, only the node G is left. So the node G is determined as a defect and reported to the lab.

Furthermore, if the resultant defect set comprises more than 1 node or is null, two methods are often utilized to handle this situation. One method is to directly deny the single stuck-at assumption and then go to step 202 to perform the multiple stuck-at assumption process when the resultant defect set is null. For more than 1 node results, the other method is to utilize more scan patterns to try and delete the suspected nodes in the result. For example, in the case shown in FIG. 3, if only the previous scan patterns 1˜7 are utilized, the nodes G and J will be determined as defects. Therefore, the scan pattern 8 can be further utilized to determine that the node j is unsuspected such that the defect G can be pointed out.

Then, if the single stuck at fault assumption cannot identify the defect (for example, the resultant defect set may comprise more than one node or comprise no node), in step 202, the multiple stuck at fault assumption is in use. The multiple stuck at fault assumption, as its name implies, assumes that the chip comprises multiple defects. In order to analyze the chip more accurately, steps 204˜210 individually utilize different methods under the basis of the multiple stuck at fault assumption.

In step 204, we assume that a single defect is located by a single chain. In other words, in step 204, one scan chain comprises only one defect. This could help the fault diagnosis to focus on a single chain instead of the whole chip (all chains). Obviously, under the above-mentioned assumption, it is easier to find out a defect in a scan chain than in the entire chip. The method of determining the defect through analyzing the suspected and unsuspected defects based on the assumption of a single defect being located by single chain can be illustrated by the following equation (2):
Single defect located on single chain=suspected defect sets_singlechains(AND)−unsuspected defect sets_allchains(OR) equation (2)

Similarly, in equation (2), suspected defects_singlechain(AND) represents the intersection of suspected defect sets of a single chain for all scan patterns, and the unsuspected defects_allchains(OR) still represents the union of unsuspected defect sets of all of the scan chains for all scan patterns. Please note, the operation of equation (2) is largely similar to equation (1). The only difference between them is: in equation (2), the intersection of suspected defect sets of “a single chain” is utilized instead of the intersection of suspected defect sets of all scan chain. That is, in equation (1), the suspected defect set is obtained according to the entire chip, and in equation (2), the suspected defect set is obtained according to a single scan chain.

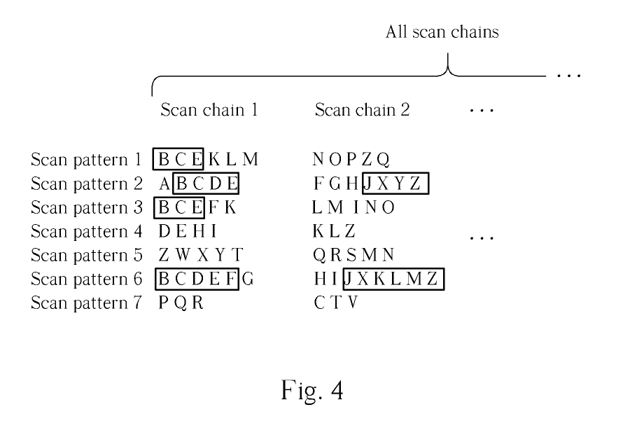

Please refer to FIG. 4, which is a simplified diagram illustrating the multiple stuck-at fault assumption where a single fault locates on a single scan chain according to the present invention. Please note, in FIG. 4, only seven scan patterns and two scan chains are shown for simplicity.

Similarly, each scan pattern corresponds a plurality of nodes, which are labeled by different characters. These characters correspond to different scan chains. In the following disclosure, under the assumption of single defect located on a single scan chain, the analysis scope is based on a single chain.

For example, for scan chain 1 and scan pattern 1, the suspected defect set comprises nodes B, C, and E. For scan pattern 2 and scan chain 1, the suspected defect set comprises nodes B, C, D, and E. For scan pattern 3 and scan chain 1, the suspected defect set comprises nodes B, C, and E, and so on.

Therefore, the intersection of suspected defect sets corresponding to scan chain 1 comprises B, C, and E. Please note, because the union is obtained by gathering passed nodes of all scan chains, the scope of the union is based on the entire chip. This means that the resultant defect set of subtracting union from the intersection does not include any one of passed nodes. In this case, for scan pattern 4 and scan chain 1, E is a passed node. For scan pattern 7 and scan chain 2, C is a passed node. Therefore, the nodes C and E are deleted from the intersection B, C, and E such that only the node B is left.

As there is only one left defect B for a scan chain 1, the defect B complies with the original assumption of single defect located on a single chain such that the defect B will be determined as a candidate defect.

On the other hand, considering the scan chain 2. the intersection of suspected defects sets is the intersection of “J, X, Y, Z” and “J, X, K, L, M, Z”. Therefore the intersection is “J, X, Z”. For scan pattern 5 and scan chain 1, the nodes X and Z are passed nodes. Therefore, the resultant defect set comprises only one node J. According to the same assumption, the node J is also determined as a candidate defect.

Similarly, the above-mentioned resultant defect set may also comprise more than one defect or no node. The solutions are also similar. One is to utilize more scan patterns to figure out the nodes of the resultant defect sets are passed or not. The other solution is to deny the assumption and proceed to a next step 206 to analyze.

In step 206, it is assumed that multiple defects are located on a single chain. Please note, here, in order to analyze the defect more easily, the sentence “multiple defects are located on a single chain” is translated as “a single defect is located on a sub-chain”. Here, the above-mentioned sub-chain is defined as a subset of a single scan chain. For example, the sub-chain may comprises a subset of flip-flops of a scan chain.

In the actual implementation, the sub-chain can be determined according to the distribution of flip-flops having suspected defects (meaning that the flip-flops do not output expect values). Because a node often influences flip-flops in the neighborhood, the flip-flops having suspected defects are often regional. Therefore, the distribution of the flip-flops having suspected defects is special and can be utilized as a rule of dividing a scan chain into several sub-chains.

The method of determining the defect through analyzing the suspected and unsuspected defects based on the assumption of a single defect is located by a subchain can be illustrated by the following equation (3):
Single defect located on a single sub-chain=suspected defect sets_Sub-chains(AND)−unsuspected defect sets_allchains(OR) equation (3)

Similarly, in equation (3), suspected defects_Subchains (AND) represents the intersection of suspected defect sets of a subchain for all scan patterns, and the unsuspected defects_allchains(OR) still represents the union of unsuspected defect sets of all of the scan chains for all scan patterns.

As the operation of equation (3) is largely similar to that of equation (2) and the only difference is that the suspected defect set is determined according to a sub-chain instead of a single chain, those skilled in the art can easily understand the related operation of the equation (3), so further illustration is omitted here. In other words, if the resultant of subtracting the union from the intersection of suspected defect sets of a sub-chain comprises only one node, it represents that the left node complies with the assumption such that the left node is determined as a defect.

If the assumption of single defect located on a sub-chain is not good for determining the defects, in step 208, the analysis scope goes to a basic element, the flip-flop. In step 208, it is assumed that a unique defect located on a flip-flop.

The method of determining the defect through analyzing the suspected and unsuspected defects based on the assumption of a unique defect is located on a flip-flop can be illustrated by the following equation (4):
Unique defect located by single flip-flop=suspected defect sets_FlipFlops(OR)−unsuspected defect sets_allchains(OR) equation (4)

In equation (4), suspected defect sets_FlipFlops(OR) represents the union of suspected defect sets of a flip-flop for all scan patterns, and the unsuspected defects_allchains(OR) still represents the union of unsuspected defect sets of all of the scan chains for all scan patterns.

Please note, unlike the equation (1)˜equation (3), the intersection is no longer used in equation (4). As a flip-flop only corresponds to a few nodes, either a sub-chain or a scan chain often correspond lots of nodes. If the intersection of suspected defect sets is still utilized in equation (4), the limitation is so restrictive that a null intersection is always obtained. Furthermore, the noun “unique defect” tries to distinguish the unique defect with the above-mentioned “single defect”, and implies that the unique defect is not the only defect that could be determined through a more restrict limitation. Instead, it is just a more likely defect corresponding to a flip-flop.

Similarly, if the resultant defect set of subtracting union of unsuspected defect sets from the union of suspected defect sets comprise only one node, then the node is determined as a unique defect. Moreover, from the equation (4), it can be easily understood that the unique defect does not have to fail in more than one scan pattern. If a node is the only one node, which is not deleted because it passes in other scan patterns, the node would be determined as a unique defect.

If the resultant defect set based on the unique defect assumption comprises more than one node and if one of these left nodes should be selected, the step 210 is performed. In step 210, the left nodes are analyzed through a statistic result. In the present invention, two statistic results are used to select one of the left nodes.

The first statistic result is the total amount of flip-flops which a node influences. For example, if node A is a failed node in 7 flip-flops and node B is a failed node only in 3 flip-flops, obviously, the node A is more likely to be a defect such that it is determined as a defect.

The second statistic result is the total amount of scan patterns where a node influences. For example, if node A is a failed node in 8 scan patterns and node B is a failed node only in 3 scan patterns, the node A is determined as a defect.

After the above-mentioned steps 200˜210, the possible defect should be pointed out such that the lab could fix the manufacturing process (step 220).

In the above-mentioned disclosure, no matter which assumption is utilized, if the resultant defect set comprises more than 1 node, a frequently-used solution is to utilize more scan patterns. As mentioned previously, if a scan pattern is further utilized, a fault simulation corresponding to the scan pattern should be performed to know the nodes corresponding to the scan pattern. The fault dictionary should comprise a large amount of data, because the fault dictionary has to be previously built before testing. Therefore, if more scan patterns should be utilized, a fault dictionary corresponding to more scan patterns should be built. It is important to build a fault dictionary, which not only corresponds to more scan patterns but also occupies a small storage space.

The solution is to compress the fault dictionary in a smart way. This is why the fault dictionary is compressed in step 106. In the following disclosure, how an original fault dictionary is compressed will be illustrated.

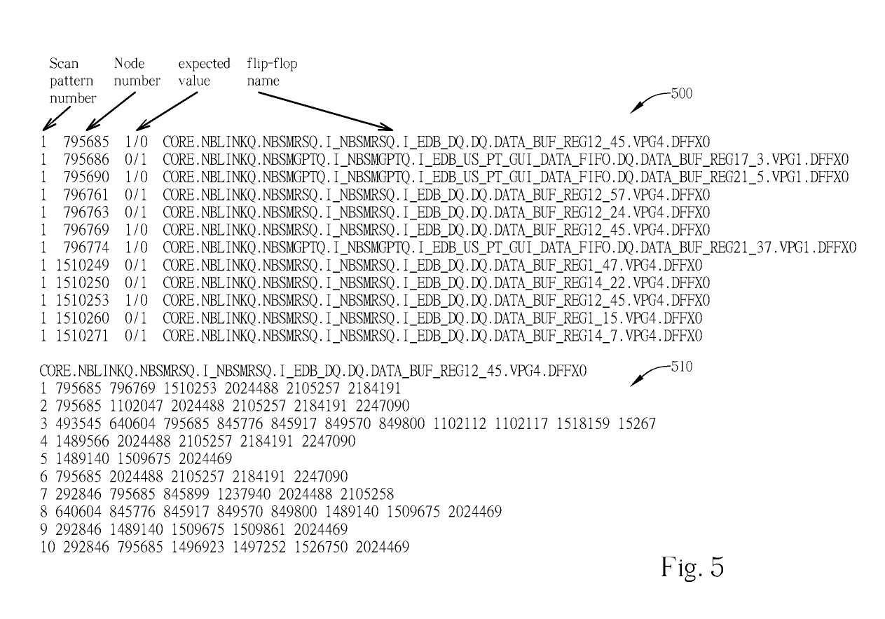

Please refer to FIG. 5, which is a diagram illustrating how an original fault dictionary is compressed into a compressed dictionary. In FIG. 5, a part of an original fault dictionary 500 and a part of a compressed dictionary 510, which are outputted by an ATPG program are shown.

In the original fault dictionary 500, each entry shows a scan pattern number, a node number, an expected value, and a flip-flop name. As is shown, the flip-flop name is long such that the flip-flop name should occupy a lot of storage space. Furthermore, for the node numbers 795685, 796769, and 1510253, the flip-flop names “COR CORE.NBLINKQ.NBSMRSQ.I_NBSMRSQ.I_EDB_DQ.DQ.DATA_BUF_REG12_{—}45.VPG4.DFFX0” are the same. This means that the nodes 795685, 796769, and 1510253 influence the flip-flop in scan pattern 1. Obviously, the long flip-flop name are repeated three times, and it is difficult to locate these three entries because the entries are distributed in the fault dictionary randomly.

Therefore, in the compressed fault dictionary 510, the entries corresponding to a specific flip-flop name are grouped; and repeated specific flip-flop names in the specific entries are deleted. In the compressed fault dictionary 510, all nodes corresponding to a scan pattern and the specific flip-flop are arranged in an entry such that it becomes easier to locate the nodes. For example, for the flip-flop “COR CORE.NBLINKQ.NBSMRSQ.I_NBSMRSQ.I_EDB_DQ.DQ.DATA_BUF_REG12_{—}45.VPG4.DFFX0”, if the node numbers 795685, 796769, and 1510253 are gathered in the entry corresponding to the scan pattern 1. This could help the efficiency and reduce the storage space.

In contrast to the prior art, the present invention discloses a method to compress the fault dictionary and a novel algorithm to find out the defects of a chip. This raises the hit rate of determining defects and reduces time and storage space when analyzing nodes of the chips.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for detecting a defect of a chip comprising:
utilizing a plurality of scan patterns to scan a plurality of scan chains of the chip;
for each of the scan patterns, obtaining at least one of a suspected defect set or an unsuspected defect set;
obtaining an intersection of all non-null suspected defect sets, wherein the non-null suspected defect sets are suspected defect sets comprising at least one suspected defect;
obtaining a union of all unsuspected defect sets corresponding to the scan patterns;
subtracting the union from the intersection to obtain a resultant suspected defect set; and
detecting the defect of the chip according to the resultant suspected defect set.

2. The method of claim 1, wherein each suspected defect set is null or comprises suspected defects of all of the scan chains, and each unsuspected defect set is null or comprises unsuspected defects of all of the scan chains.

3. The method of claim 2, wherein the step of detecting the defect of the chip further comprises:
if the resultant suspected defect set comprises only one suspected defect, determining the suspected defect as the defect of the chip.

4. The method of claim 1, wherein each suspected defect set is null or comprises suspected defects of a specific scan chain of the scan chains, and each unsuspected defect set is null or comprises unsuspected defects of all of the scan chains.

5. The method of claim 4, wherein the step of detecting the defect of the chip further comprises:
if the resultant suspected defect set comprises only one suspected defect, determining the suspected defect as the defect of the chip.

6. The method of claim 1, wherein each suspected defect set is null or comprises suspected defects of a sub-chain of a specific scan chain of the scan chains, and each unsuspected defect set is null or comprises unsuspected defects of all of the scan chains.

7. The method of claim 6, wherein the step of detecting the defect of the chip further comprises:
if the resultant suspected defect set comprises only one suspected defect, determining the suspected defect as the defect of the chip.

8. The method of claim 6, wherein each of the scan chains comprises a plurality of flip-flops, and the method further comprises:
determining the sub-chain of the specific scan chain according to a distribution of flip-flops of the specific scan chain corresponding to suspected defects.

9. The method of claim 1, wherein the method further comprises:
building a fault dictionary through performing fault simulations;
compressing the fault dictionary to generate a compressed fault dictionary;
and the step of obtaining the suspected defect set and the unsuspected defect set comprises:
obtaining the suspected defect set and the unsuspected defect set by looking up the compressed fault dictionary.

10. The method of claim 9, wherein each of the scan chains comprises a plurality of flip-flops, the fault dictionary comprises a plurality of entries each having a flip-flop name, and the step of compressing the fault dictionary comprises:
grouping a plurality of specific entries corresponding to a specific flip-flop name; and
deleting repeated specific flip-flop names in the specific entries.

11. A method for detecting a defect of a chip comprising:
utilizing a plurality of scan patterns to scan a plurality of scan chains of the chip, each of the scan chains comprising a plurality of flip-flops;
for each of the scan patterns, obtaining at least one of a suspected defect set of a specific flip-flop or an unsuspected defect set of all of the scan chains;
obtaining a first union of all suspected defect sets of the specific flip-flop;
obtaining a second union of all unsuspected defect sets corresponding to the scan patterns;
subtracting the second union from the first union to obtain a resultant suspected defect set; and
detecting the defect of the chip according to the resultant suspected defect set.

12. The method of claim 11, wherein the step of detecting the defect of the chip further comprises:
if the resultant suspected defect set comprises only one suspected defect, determining the suspected defect as the defect of the chip.

13. The method of claim 11, wherein the step of detecting the defect of the chip further comprises:
if the resultant suspected defect set comprises a plurality of suspected defects, selecting a specific suspected defect out of the resultant suspected defect set, wherein in the resultant suspected defect set, the specific suspected defect is most frequently found utilizing all of the scan patterns.

14. The method of claim 11, wherein the step of detecting the defect of the chip further comprises:
if the resultant suspected defect set comprises a plurality of suspected defects, selecting a specific suspected defect out of the resultant suspected defect set, wherein in the resultant suspected defect set, the specific suspected defect affects most flip-flops.

15. The method of claim 11, wherein the method further comprises:
building a fault dictionary through performing fault simulations;
compressing the fault dictionary to generate a compressed fault dictionary;
and the step of obtaining the suspected defect set and the unsuspected defect set comprises:
obtaining the suspected defect set and the unsuspected defect set by looking up the compressed fault dictionary.

16. The method of claim 15 wherein each of the scan chains comprises a plurality of flip-flops, the fault dictionary comprises a plurality of entries each having a flip-flop name, and the step of compressing the fault dictionary further comprises:
grouping a plurality of specific entries corresponding to a specific flip-flop name; and
deleting at least one repeated specific flip-flop name in the specific entries.

17. A method for detecting a defect of a chip comprising:
utilizing a plurality of scan patterns to scan a plurality of scan chains of the chip;
building a fault dictionary through performing fault simulations, where the fault dictionary comprises a plurality of entries each having a flip-flop name;
compressing the fault dictionary to generate a compressed fault dictionary by grouping a plurality of specific entries corresponding to a specific flip-flop name and deleting repeated specific flip-flop names in the specific entries;
obtaining the suspected defect set and the unsuspected defect set by looking up the compressed fault dictionary; and
analyzing the suspected defects and the unsuspected defects to determine the defect of the chip.
